(19) United States
(12) Patent Application Publication
(10) Pub. No.: US 2022/0158107 A1
(43) Pub. Date: May 19, 2022

(54) STRUCTURE AND METHOD FOR PATTERNED QUANTUM DOTS LIGHT EMITTING DIODES (QLEDS)

(71) Applicant: SHARP KABUSHIKI KAISHA, Osaka (JP)

(72) Inventor: ENRICO ANGIONI, Didcot (GB)

(21) Appl. No.: 17/097,451

(22) Filed: Nov. 13, 2020

(51) Int. Cl. H01L 51/50

(52) U.S. Cl. CPC H01L 51/502; H01L 51/5056; H01L 51/5072; H01L 2251/558; H01L 51/5092; H01L 51/5096; H01L 51/5088

(57) ABSTRACT

A light-emitting device includes an anode, a cathode, an electron transporting or injecting layer between the cathode and the anode, an emissive layer having quantum dots between the anode and the electron transporting or injecting layer, and a cross-linked hole transporting or injecting layer between the anode and the emissive layer. The cross-linked hole transporting or injecting layer includes a cross-linked material formed by a cross-linkable material cross-linked by at least one of a stimulus or an initiator. The stimulus is an external stimulus including one of light, a change in temperature, a change in pressure and a change in pH value.

### FIELD

The present disclosure relates to a layer structure applicable in an emissive device, in particular for a Quantum Dot LED. Specifically, a QLED structure and a method to patterned red, green and blue subpixels are disclosed herein.

### BACKGROUND

A common architecture for a light-emitting device includes an anode, which functions as a hole injector; a hole transport layer disposed on the anode; an emissive material layer disposed on the hole transport layer; an electron transport layer disposed on the emissive material layer; and a cathode, which functions as an electron injector, disposed on the electron transport layer. When a forward bias is applied between the anode and cathode, holes and electrons are transported in the device through the hole transport layer and the electron transport layer, respectively. The holes and electrons recombine in the emissive material layer; light is generated and emitted from the device. When the emissive material layer includes an organic material, the light-emitting device is referred to as an organic light-emitting diode (OLED). When the emissive material layer includes nanoparticles, sometimes known as quantum dots (QDs), the device is commonly referred to as either a QD light-emitting diode (QLED, QD-LED) or an electroluminescent QD light-emitting diode (ELQLED, QDEL).

The above described layers are deposited on a substrate, different structures can be achieved by changing an order of deposition of the layers. In a non-inverted (e.g., standard) structure, the first layer deposited on the substrate is the anode, followed by the hole transporting layer, the emissive layer, the electron transporting layer and finally by the cathode. In an inverted structure, these layers are deposited on the substrate on the opposite order, starting with the cathode and finishing with the anode.

Difference methods can be utilized to deposit each of the above described layers of the light-emitting device, such as thermal evaporation methods and solution process methods. Thermal evaporation methods used for OLEDs are more complex, and have higher costs of fabrication as compared to solution process methods. Solution process methods are thus preferred as they are less complex and more cost effective.

However, in the fabrication of devices with the solution methods, finding appropriate (e.g., non-damaging) solvents is important because during the deposition of a particular layer, the process should not dissolve or otherwise damage the previously deposited layer. Such a non-damaging solvent is typically referred to as “orthogonal” to the previous layer (See Organic Electronics 30 (2016) 18e29; http://dx.doi.org/10.1016/j.orgel.2015.12.008).

To include QLEDs in multi-color high resolution displays, different manufacturing methods have been designed. These methods typically include depositing three different types of QDs on three different regions of a substrate such that each region emits light (through electrical injection; i.e., by electroluminescence) of three different colors, particularly red (R), green (G) and blue (B). Sub-pixels that respectively emit red, green, or blue light may collectively form a pixel, which in turn may be a part of an array of pixels of the display.

Despite the fact that inverted structures for QLEDs are common in applications, most of the reported solution processed methods for including QLEDs in multi-color high resolution displays, are designed principally for QLEDs with non-inverted (e.g., standard) structures. Therefore, there is a need to achieve patterned QLEDs in both inverted and non-inverted structures and manufacturing methods of the same.

### CITATION LIST

WO 2017/117994 by Li et al., published Jul. 13, 2017.

WO 2017/121163 by Li et al., published Jul. 20, 2017.

Alternative Patterning Process for Realization of Large-Area′ by Park et al., Full-Color, Active Quantum Dot Display, Nano Letters, 2016, pages 6946-6953.

CN106374056A by X. Chao, published Jan. 2, 2017.

### SUMMARY

The present disclosure is related to a QLED structure and a method to patterned red, green and blue subpixels.

According to a first aspect of the present disclosure, a light-emitting device includes an anode, a cathode, an electron transporting or injecting layer between the cathode and the anode, an emissive layer having quantum dots between the anode and the electron transporting or injecting layer, and a cross-linked hole transporting or injecting layer between the anode and the emissive layer.

According to an implementation of the first aspect, the cross-linked hole transporting or injecting layer comprises a cross-linked material formed by a cross-linkable material cross-linked by at least one of a stimulus or an initiator.

According to another implementation of the first aspect, the stimulus is an external stimulus including one of light, a change in temperature, a change in pressure and a change in pH value.

According to yet another implementation of the first aspect, the light-emitting device further includes a hole injecting layer between the cross-linked hole transporting or injecting layer and the anode.

According to yet another implementation of the first aspect, the light-emitting device further includes at least one electron blocking layer, wherein the at least one electron blocking layer is situated in at least one of the following positions: between the emissive layer and the cross-linked hole transporting layer; and between the electron transporting layer and the emissive layer.

According to yet another implementation of the first aspect, the initiator is a photo initiator that initiates polymerization of the cross-linkable material in response to a light stimulus.

According to yet another implementation of the first aspect, the light stimulus that activates the photo initiator is in an ultraviolet (UV) wavelength range of an electromagnetic spectrum.

According to yet another implementation of the first aspect, the cross-linkable material is deposited on the emissive layer in a solution.

According to a second aspect of the present disclosure, a light-emitting device includes an anode, a cathode, a hole transporting or injecting layer between the cathode and the anode, an emissive layer having quantum dots between the cathode and the hole transporting or injecting layer, and a cross-linked electron transporting or injecting layer between the cathode and the emissive layer.

According to an implementation of the second aspect, the cross-linked electron transporting or injecting layer comprises a cross-linked material formed by a cross-linkable material cross-linked by at least one of a stimulus or an initiator.

According to another implementation of the second aspect, the stimulus is an external stimulus including one of light, a change in temperature, a change in pressure and a change in pH value.

According to yet another implementation of the second aspect, the light-emitting device further includes a hole injecting layer between the hole transporting or injecting layer and the anode.

According to yet another implementation of the second aspect, the light-emitting device further includes at least one electron blocking layer, wherein the at least one electron blocking layer is situated in at least one of the following positions: between the emissive layer and the cross-linked electron transporting layer; and between the hole transporting layer and the emissive layer.

According to yet another implementation of the second aspect, the initiator is a photo initiator that initiates polymerization of the cross-linkable material in response to a light stimulus.

According to yet another implementation of the second aspect, the light stimulus that activates the photo initiator is in an ultraviolet (UV) wavelength range of an electromagnetic spectrum.

According to yet another implementation of the second aspect, the cross-linkable material is deposited on the emissive layer in a solution.

According to a third aspect of the present disclosure, a light-emitting device includes a substrate and a plurality of sub-pixel structures over the substrate. At least one of the plurality of sub-pixel structures includes: an anode, a cathode, an electron transporting or injecting layer between the cathode and the anode, an emissive layer having quantum dots between the anode and the electron transporting or injecting layer, and a cross-linked hole transporting or injecting layer between the anode and the emissive layer.

According to an implementation of the third aspect, the cross-linked hole transporting or injecting layer includes a cross-linked material formed by a cross-linkable material cross-linked by at least one of a stimulus or an initiator.

According to another implementation of the third aspect, a thickness of the emissive layer in each of the plurality of sub-pixel structures is different.

According to another implementation of the third aspect, at least one of a thickness and a composition of the cross-linked hole transporting or injecting layer in each of the plurality of sub-pixel structures is different.

### BRIEF DESCRIPTION OF THE DRAWINGS

Aspects of the example disclosure are best understood from the following detailed description when read with the accompanying figures. Various features are not drawn to scale. Dimensions of various features may be arbitrarily increased or reduced for clarity of discussion.

FIG. 1A is a schematic representation of a related art core-shell QD.

FIG. 1B is a simplified schematic representation of the related art core-shell QD in FIG. 1A.

FIG. 2 illustrates a cross-sectional view of a related art quantum dot light-emitting diode (QLED).

FIG. 3A illustrates a cross-sectional view of a non-inverted QLED structure in accordance with an example implementation of the present disclosure.

FIG. 3B illustrates a cross-sectional view of an inverted QLED structure in accordance with an example implementation of the present disclosure.

FIG. 4 illustrates an inverted QLED structure in accordance with an example implementation of the present disclosure.

FIG. 5A to FIG. 5P illustrate a method of making a pattered QLED with an inverted structure in accordance with an example implementation of the present disclosure.

FIG. 6A illustrates a non-inverted QLED structure according to the present disclosure.

FIG. 6B illustrates a non-inverted QLED structure according to another example implementation of the present disclosure.

FIG. 7A to FIG. 7P illustrate a method of making a light emitting structure having pattered QLEDs with non-inverted structures in accordance with an example implementation of the present disclosure.

FIG. 8 illustrates a light emitting structure having patterned QLEDs with inverted structures, each subpixel having a different type of QDs and a hole transporting layer (HTL) of a different thickness, manufactured according to the method disclosed from FIG. 5A to FIG. 5P.

FIG. 9 illustrates a light emitting structure having patterned QLEDs with non-inverted structures, each subpixel having a different type of QDs and an electron transporting layer (ETL) of a different thickness, manufactured according to the method disclosed from FIG. 7A to FIG. 7P.

FIG. 10 illustrates a light emitting structure having patterned QLEDs with inverted structures, each subpixel having a different type of cross-linked hole transporting layer (X-HTL), in accordance with an example implementation of the present disclosure.

FIG. 11 illustrates an example light emitting structure having patterned QLEDs with non-inverted structures, each subpixel having a different type of cross-linked electron transporting layer (X-ETL), in accordance with an example implementation of the present disclosure.

### DESCRIPTION

The following description contains specific information pertaining to example implementations in the present disclosure. The drawings in the present disclosure and their accompanying detailed description are directed to merely example implementations. However, the present disclosure is not limited to merely these example implementations. Other variations and implementations of the present disclosure will occur to those skilled in the art. Unless noted otherwise, like or corresponding elements among the figures may be indicated by like or corresponding reference numerals. Moreover, the drawings and illustrations in the present disclosure are generally not to scale, and are not intended to correspond to actual relative dimensions.

For consistency and ease of understanding, like features may be identified (although, in some examples, not shown) by numerals in the example figures. However, the features in different implementations may be different in other respects, and thus shall not be narrowly confined to what is shown in the figures.

The phrases “in one implementation,” or “in some implementations,” may each refer to one or more of the same or different implementations. The term “coupled” is defined as connected, whether directly or indirectly through intervening components, and is not necessarily limited to physical connections. The term “comprising” means “including, but not necessarily limited to” and specifically indicates open-ended inclusion or membership in the so-described combination, group, series and equivalents. The expression “at least one of A, B and C” or “at least one of the following: A, B and C” means “only A, or only B, or only C, or any combination of A, B and C.”

Additionally, any two or more of the following paragraphs, (sub)-bullets, points, actions, behaviours, terms, alternatives, examples, or claims described in the following disclosure may be combined logically, reasonably, and properly to form a specific method. Any sentence, paragraph, (sub)-bullet, point, action, behaviours, terms, or claims described in the following disclosure may be implemented independently and separately to form a specific method. Dependency, e.g., “according to”, “more specifically”, “preferably”, “In one embodiment”, “In one implementation”, “In one alternative” etc., in the following disclosure refers to just one possible example which would not restrict the specific method.

For explanation and non-limitation, specific details, such as functional entities, techniques, protocols, and standards are set forth for providing an understanding of the described technology. In other examples, detailed description of well-known methods, technologies, system, and architectures are omitted so as not to obscure the description with unnecessary details.

The present disclosure is related to a specific structure of a QLED, a method to achieve it and a fabrication method to achieve multi-color high resolution displays based on QLEDs with this structure.

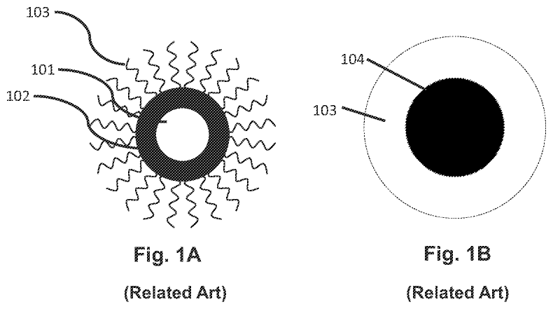

FIG. 1A and FIG. 1B are drawings each depicting a two-dimensional schematic representation of a related art core-shell QD as may be employed in an emissive layer. QDs are defined as particles with a physical radius which is smaller than the exciton Bohr radius. The QDs may be configured as nanoparticles. A nanocrystalline core 101 is co-crystallised with a shell of a compatible material 102, which is then surrounded by ligands 103 that passivate crystal defects in the core-shell QD and allow and improve solubility in common solvents. FIG. 1B is a schematic simplified version of FIG. 1A used for more convenient representation of QDs in a light-emitting device structure, depicting a generalized core-shell QD structure 104 surrounded by a region of ligands 103.

It will be appreciated that while the present disclosure primarily describes the QDs as core-shell QDs, in some implementations the QDs may not be of the core-shell type or they may be of a core/multiple-shells type having more than one shell. The non-core-shell type QDs may be made from one or more of the above-mentioned materials, and the QDs in accordance with the present disclosure may not include a core-shell configuration.

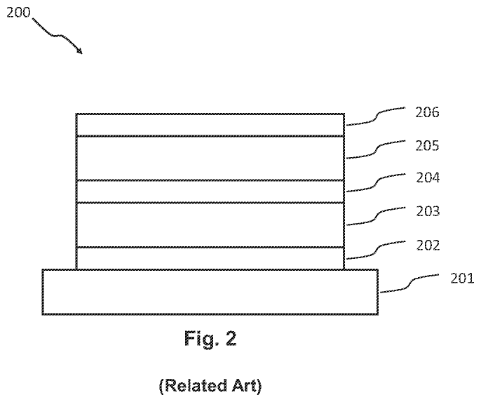

The present disclosure may be understood with reference to FIG. 2, which illustrates the basic structure of a QLED 200. A first electrode 202 is arranged on a substrate 201, with a second electrode 206 arranged opposite the first electrode on the same side of the substrate. An emissive layer (EML) 204, which contains QDs, is arranged between the first and second electrodes and is in electrical contact with the first and second electrodes. Additional layers 203 and 205 may be present between an electrode and the EML, such as one or more charge injection layers, charge transport layers and charge blocking layers.

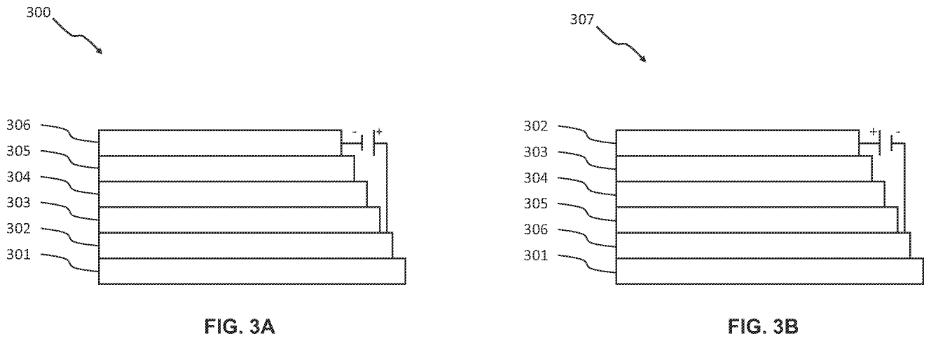

In the non-inverted structure 300 in FIG. 3A, the electrode closer to the substrate 301 is an anode 302, and the layer 303 between the anode 302 and the EML 304 may include one or more layers, such as hole injection layers, hole transporting layers, electron blocking layers and/or hole blocking layers. Similarly, the electrode furthest from the substrate 301 is a cathode 306, and the layer 305 between the cathode 306 and the EML 304 may include one or more layers, such as electron injection layers, electron transporting layers, hole blocking layers and/or electron blocking layers. The positions of the anode 302 and cathode 306, along with all injection, transport and blocking layers 303 and 305 may be reversed, in which case the device is said to have the “inverted” structure 307 in FIG. 3B.

When an electrical bias is applied to the QLED 300 or 307, holes are conducted from the anode 302 to the EML 304, and electrons are conducted from the cathode 306 to the EML. Holes and electrons recombine at the QDs in the EML 304, thereby generating light. Some of this light is emitted out of the QLED 300 or 307 where it may be perceived by an external viewer, thereby providing a light-emitting device. Light may be emitted through the substrate 301, in which case the device is called “bottom-emitting”, or opposite the substrate, in which case the device is called “top-emitting”.

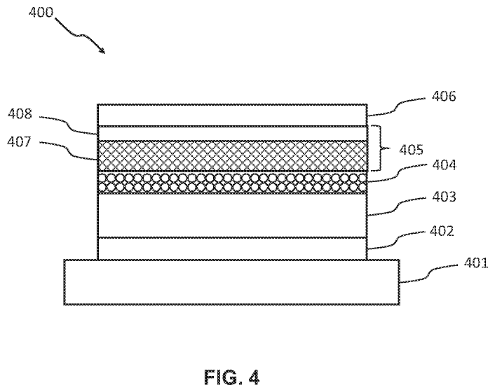

In the present disclosure, an inverted bottom emitting QLED structure is first described. The structure, depicted in FIG. 4, describes a subpixel 400 where several planar layers are disposed on a substrate 401, including: a cathode 402; an anode 406; an emissive layer (EML) 404 consisting of QDs disposed between the cathode 402 and the anode 406; one or more electron injection/transport layers (EIL/ETL) 403 disposed between the cathode 402 and the emissive layer 404; and one or more hole injection/transport layers 405 disposed between the anode 406 and the emissive layer 404. One of these hole injection/transport layers 405, in particular the one adjacent to the EML 404, is formed by a cross-linkable organic (or organo-metallic) material with hole injection/transporting properties 407 that can be cross-linked applying an external stimulus (e.g. light, temperature, difference in pH).

The cross-linkable hole transporting material can be intrinsically cross-linkable or it may need an initiator of the polymerisation. If the HTM is intrinsically cross-linkable (it can be cross-linked simply applying an external stimulus), the deposited solution that forms the HTL may comprise only a cross-linkable material and a solvent. If the HTM is not intrinsically cross-linkable (it cannot be cross-linked simply applying an external stimulus), this solution may also include one or more initiators of the polymerisation. The initiator can be defined based on the external stimulus (light, temperature, pressure, and change in pH) that activate it. For example, a photo initiator is a material that initiates polymerization in response to light stimuli. In various implementations of the present disclosure, the photo initiator may generate one or more radicals, ions, acids, and/or species that may initiate such polymerization. In the same fashion, a thermal initiator is a material that initiates polymerization in response to thermal stimuli, as a change in temperature.

In this structure, the HTL 407 adjacent to the EML 404 is cross-linked and results in a layer that is resistant to solvent rinsing. This is beneficial because it allows the use of an HIL that can be deposited with a solution processed method (e.g. spin coating, spray coating, inkjet coating and the like) without damaging the HTL and EML. As seen in the prior art, most of inverted QLED structures include a HTL and HIL deposited by vacuum thermal evaporation (J. Mater. Chem. C, 2014, 2, 510, DOI: 10.1039/c3tc31297f; ACS Appl. Mater. Interfaces 2018, 10, 17295-17300, DOI: 10.1021/acsami.8b05092; Nanoscale, 2018, 10, 592, DOI: 10.1039/c7nr06248f).

To include QLEDs in multi-color high resolution displays, three different types of QDs on three different regions of a substrate should be deposited such that each region emits light (through electrical injection; i.e. by electroluminescence) at three different colors, particularly red (R), green (G) and blue (B). Sub-pixels that respectively emit red, green, or blue light may collectively form a pixel, which in turn may be a part of an array of pixels of the display.

In some implementations of the present disclosure, a light emitting structure having RGB patterned QLEDs with inverted structures is provided.

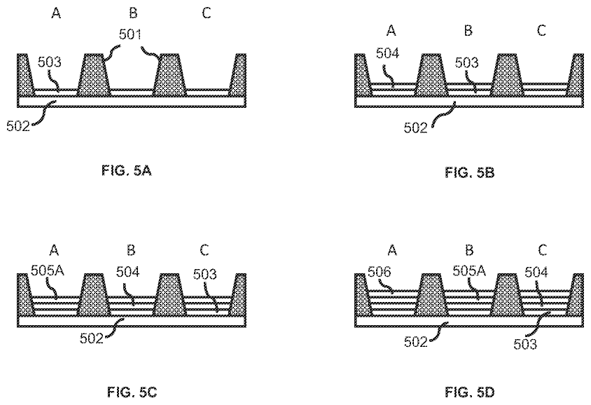

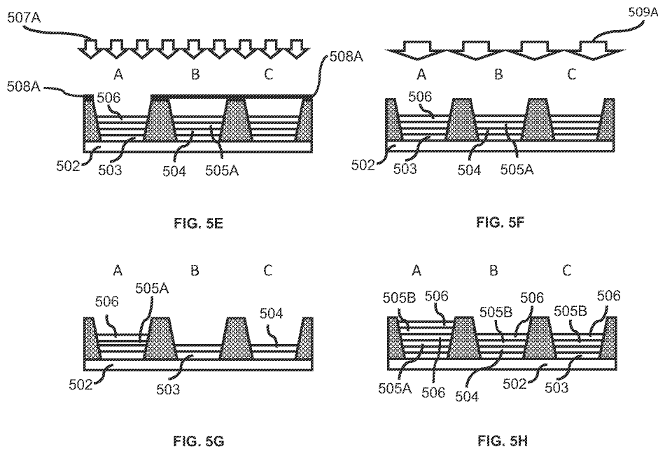

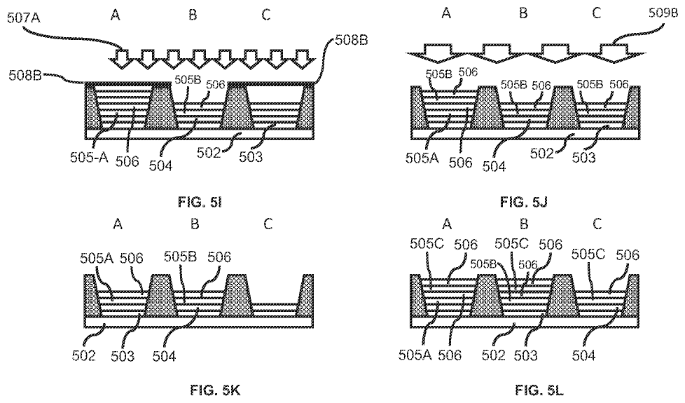

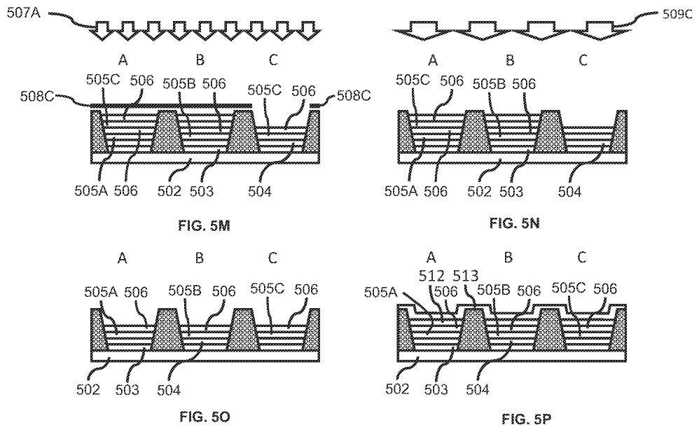

FIGS. 5A to 5P (not in scale) illustrate a method of forming three different QLEDs on three different regions of a substrate. Light-emitting devices may be arranged such that the light-emitting devices are separated at least in part by one or more insulating materials. This arrangement may also be referred to as a “bank structure.”

FIGS. 5A-5P are drawings illustrating a cross-section view of a bank structure that can allocate multiple light-emitting devices formed in accordance with implementations of the present disclosure. In a specific implementation, there are three areas labeled A, B and C in order to distinguish three different sub-pixels.

In the fabrication of the QLED according to the present disclosure, it is important to find the appropriate solvents such that during the deposition of a particular layer, a rinsing process will not dissolve or otherwise damage the previously deposited layer. Such a non-damaging solvent is typically referred to in the art as “orthogonal” to the previous one (See Organic Electronics 30 (2016) 18e29; http://dx.doi.org/10.1016/j.orgel.2015.12.008).

To deposit multiple layers in a QLED structure using solution process methods, solution of different materials in adjacent orthogonal solvents should be deposited. Solution process methods include, but are not limited to, methods of drop casting, spin coating, dip coating, slot die coating, spray coating, and inkjet printing.

In one implementation, the electron transporting material (e.g. ZnO) is dissolved and deposited in Ethanol, the emissive material (e.g. QDs) is dissolved and deposited in octane, the cross-linkable hole transporting material (e.g. OTPD) is dissolved and deposited in toluene (or in PGMEA, or in THF, or in chlorobenzene, or in 1,4-dioxane), and the hole injection material (e.g. PEDOT:PSS-MoO₃) is dissolved and deposited in an ethanol/2-propanol mixture, or PEDOT:PSS is dissolved and deposited in Toluene.

In FIG. 5A, a cathode 503 is deposited on top of a substrate 502 with banks 501 shaped in order to accommodate three areas A, B, and C representing three different sub-pixels. The cathode 503 may be the same in the three areas or different for each area.

In FIG. 5B, at least one electron transporting layer (ETL) 504 is deposited on top of the cathode 503.

In FIG. 5C, a layer 505A of QDs of type A is deposited on top of the ETL 504.

In FIG. 5D, a layer 506 of a UV cross-linkable hole transporting material is deposited. The material can be cross-linked (polymerised) when exposed to UV light of specific energy.

In FIG. 5E, the UV cross-linkable layer 506 is exposed to UV light 507A only in correspondence of a specific area of the substrate (area A in this specific implementation), delimitated by the use of a shadow mask 508A. A layer of cross-linked hole transporting material is obtained in the area A, this area is now resistant to rinsing with a specific solvent or developer 509A.

In FIG. 5F, the substrate with the deposited layers is rinsed with the solvent or developer 509A that washes away 505A of QDs A and the layer 506 of cross-linkable hole transporting material that are not in the area A.

FIG. 5G illustrates the three areas A, B, and C after the first rinsing wherein the area A retains the layers 503, 504, 505A, and 506 deposited up to FIG. 5D, while in the areas B and C, the cathode 503 and the electron transporting layer 504 remain.

In FIG. 5H, a layer 505B of QDs of type B and subsequently a layer 506 of UV cross-linkable hole transporting material are deposited.

In FIG. 5I, the UV cross-linkable layer 506 is exposed to UV light 507A only in correspondence of a specific area of the substrate (area B in this specific implementation), delimitated by the use of a shadow mask 508B. A layer of cross-linked hole transporting material is obtained in the area B, this area is now resistant to rinsing with a specific solvent or developer 509B.

In FIG. 5J, the substrate with the deposited layers is rinsed with the solvent or developer 509B that washes away the 505B layers of QDs B and of the 506 layer of cross-linkable hole transporting material that is not in the area B.

FIG. 5K illustrates the three areas A, B, and C after the second rinsing wherein the area B retains layers 503, 504, 505B, and 506 deposited in FIG. 5H, while the area A retains the layers deposited up to FIG. 5G, and the area C retains the cathode 503 and the electron transporting layer 504.

In FIG. 5L, a layer 505C of QDs of type C and subsequently a layer 506 of UV cross-linkable hole transporting material are deposited.

In FIG. 5M, the UV cross-linkable layer 506 is exposed to UV light 507A only in correspondence of a specific area of the substrate (area C in this specific implementation), delimitated by the use of a shadow mask 508C. A layer of cross-linked hole transporting material is obtained in the area C, this area is now resistant to rinsing with a specific solvent or developer 509C.

In FIG. 5N, the substrate with the deposited layers is rinsed with the solvent or developer 509C that washes away the layers 505C of QDs C and the layers 506 of the cross-linkable hole transporting material that are not in the area C.

FIG. 5O illustrates the three areas A, B, and C after the third rinsing wherein the area C retains the layers 503, 504, 505C, and 506 deposited in FIG. 5L, while the area A retains the layers deposited up to FIG. 5G, and the area B retains the layers deposited up to FIG. 5K.

In FIG. 5P, a hole injection layer 512 and subsequently an anode 516 are deposited to create three QLED subpixels in the three different areas A, B and C.

The thickness of each layers deposited in FIGS. 5A to 5P ranges from 1 to 150 nm.

The method can be applied also for a non-inverted structure and a cross-linkable electron injecting/transporting layer. This will be detailed in one of the implementations.

A three color display can be produced utilizing the above described structure and the method described in the present disclosure. The three color display has the following characters:
A thickness of each of the three EMLs can be different.
A thickness of the cross-linkable hole transporting material (X-HTM) in each of the three areas can be different.
A different type of cross-linkable hole transporting materials can be used in each of the three areas; each of the X-HTM can have a different thickness. Specifically, a first X-HTM A can be deposited in FIG. 5D; a second X-HTM B can be deposited in FIG. 5H; and a third X-HTM C can be deposited in FIG. 5L.
Inverted QLED structure enables utilization of IGZO (n-type) backplane with much lower ageing/burn-in effect.
An X-HTL 407 composed of more than one X-HTM can be used. The mixture of HTMs can be designed to achieve a specific energy level matching with the band gap energies of the EML and the HIL or the anode.
The mixture of HTMs can be designed to achieve a specific hole mobility, and/or adding insulating or more conductive materials, since the HTMs do not need to be cross-linkable.
Another interlayer (e.g., an electron blocking interlayer) may be deposited between the EML and the X-HTM, a material for this interlayer can be different for each subpixel, and a thickness of this interlayer layer can be controlled in each subpixel.
Another interlayer (e.g., a hole transporting interlayer or an electron blocking layer interlayer) may be deposited between the ETL and the EML, a material of this interlayer can be different for each subpixel, and a thickness of this interlayer can be controlled in each subpixel.

In some implementations of the present disclosure, a light emitting structure having patterned QLEDs with non-inverted structures is provided.

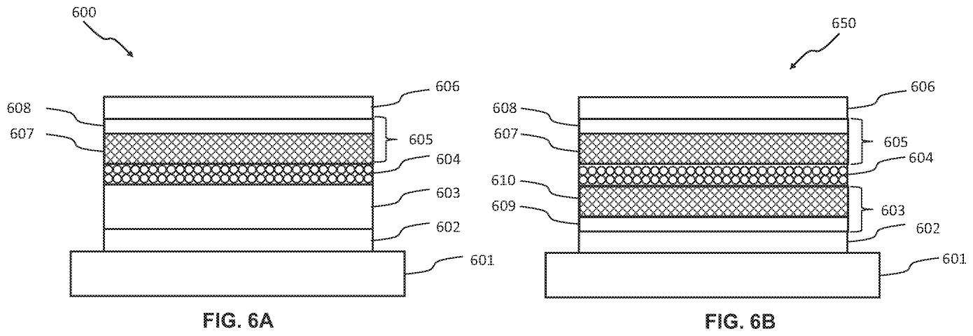

FIG. 6A illustrates an implementation according to the present disclosure. A QLED subpixel 600 with a non-inverted structure is composed of several planar layers disposed on a substrate 601, including: an anode 602; an cathode 606; an emissive layer (EML) 604 consisting of QDs disposed between the anode 602 and the cathode 606; one or more hole injection/transport layers (HIL/HTL) 603 disposed between the anode 602 and the emissive layer 604; and one or more electron injection/transport layers 605 disposed between the cathode 606 and the emissive layer 604. One of these electron injection/transport layers 605, in particular the one adjacent to the EML 604, is formed by a cross-linkable organic (or organo-metallic) material with electron injection/transporting properties 607 that can be cross-linked applying an external stimulus (e.g. light, temperature, difference in pH).

FIG. 6B illustrates another implementation according to the present disclosure. A QLED subpixel 650 is similar to the QLED subpixel 600, except that the one or more hole injection/transport layers (HIL/HTL) 603 comprises an hole injection layer 609 of an organic (or organo-metallic) material, and a hole transporting layer 610 which can be cross-linked applying an external stimulus (e.g. light, temperature, difference in pH).

In some implementations of the present disclosure, a light emitting structure having RGB patterned QLEDs with non-inverted structures is provided.

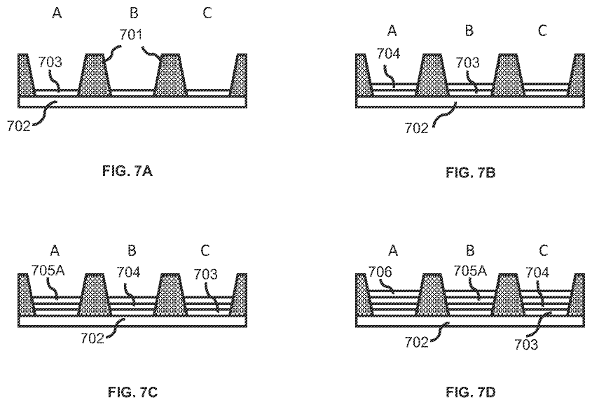

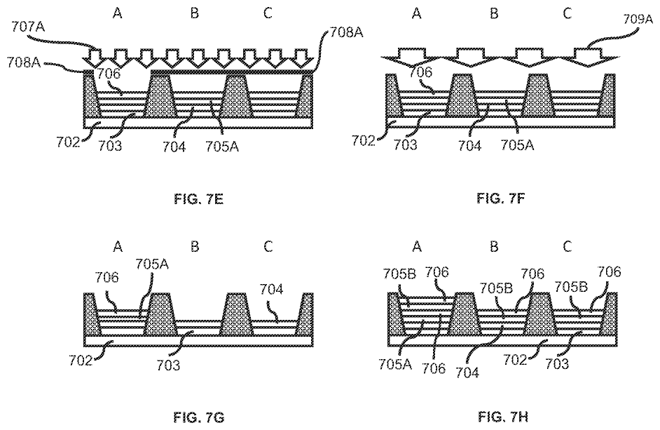

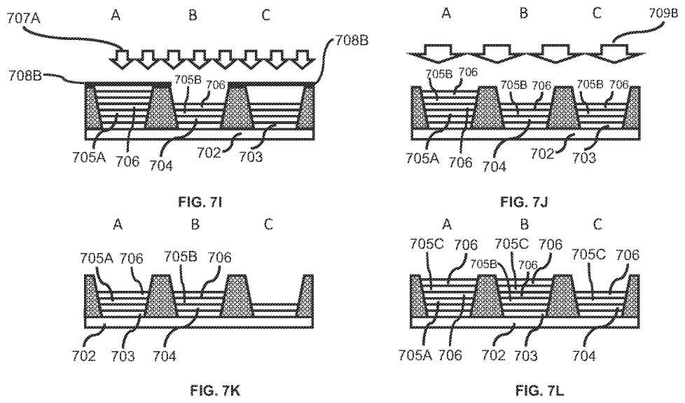

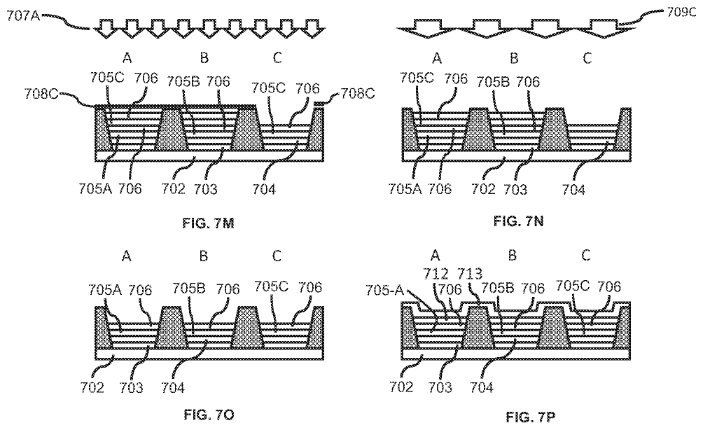

FIGS. 7A-7P (not in scale) illustrate a method of forming three different QLED with a non-inverted structure on three different areas of a substrate. These three areas may be sub-pixels that respectively emit light of three different colours and that may collectively form a pixel, which in turn may be a part of an array of pixels of the display.

Light-emitting devices may be arranged such that the light-emitting devices are separated at least in part by one or more insulating materials. This arrangement may also be referred to as a “bank structure.” FIGS. 7A-7P illustrate a cross-section view of a bank structure 701 that can allocate multiple light-emitting devices formed in accordance with implementations of the present disclosure. In a specific implementation there are three areas labeled A, B and C in order to distinguish three different sub-pixels.

In FIG. 7A, an anode 703 is deposited on top of a substrate 702 with banks 701 shaped in order to accommodate three areas A, B, and C representing three different sub-pixels. The anode 702 can be the same in the three areas or different for each area.

In FIG. 7B at least one hole injecting/transporting layer (HIL/HTL) 704 is deposited on top of the anode 703.

In FIG. 7C, a layer 705A of QDs of type A is deposited on top of the HIL/HTL 704.

In FIG. 7D, a layer 706 of a UV cross-linkable electron transporting material is deposited. The material can be cross-linked (polymerised) when exposed to UV light of specific energy.

In FIG. 7E, the UV cross-linkable layer 706 is exposed to UV light 707A only in correspondence of a specific area of the substrate (area A in this specific implementation), delimitated by the use of a shadow mask 708A. A layer of cross-linked electron transporting material is obtained in the area A, this area is now resistant to rinsing with a specific solvent or developer 709A.

In FIG. 7F, the substrate with the deposited layers is rinsed with the solvent or developer 709A that washes away 705A of QDs A and cross-linkable layer 706 of the cross-linkable electron transporting material that are not in the area A.

FIG. 7G illustrates the three areas A, B, and C after the first rinsing wherein the area A retains the layers 703, 704, 705A, and 706 deposited up to FIG. 7D, while in the areas B and C, the anode 706 and the hole injecting/transporting layers 704 remain.

In FIG. 7H, a layer 705B of QDs of type B and subsequently a cross-linkable layer 706 of UV cross-linkable electron transporting material are deposited.

In FIG. 7I, the cross-linkable layer 706 is exposed to UV light 707A only in correspondence of a specific area of the substrate (area B in this specific implementation), delimitated by the use of a shadow mask 708B. A layer of cross-linked electron transporting material is obtained in the area B, this area is now resistant to rinsing with a specific solvent or developer 709B.

In FIG. 7J, the substrate with the deposited layers is rinsed with the solvent or developer 709B that washes away the 705B layers of QDs B and the cross-linkable layer 706 of the cross-linkable electron transporting material that are not in the area B.

FIG. 7K illustrates the three areas A, B, and C after the second rinsing wherein the area B retains the layers 703, 704, 705B, and 706 deposited in FIG. 7H, while the area A retains the layer deposited up to FIG. 7G, and the area C retains the anode 703 and the hole injecting/transporting layers 704.

In FIG. 7L, a layer 705C of QDs of type C and subsequently a cross-linkable layer 706 of UV cross-linkable electron transporting material are deposited.

In FIG. 7M, the cross-linkable layer 706 is exposed to UV light 707A only in correspondence of a specific area of the substrate (area C in this specific implementation), delimitated by the use of a shadow mask 708C. A layer of cross-linked electron transporting material is obtained in the area C, this area is now resistant to rinsing with a specific solvent or developer 709C.

In FIG. 7N, the substrate with the deposited layers is rinsed with the solvent or developer 709C that washes away the layers 705C of QDs C and the layers 706 the cross-linkable electron transporting material that are not in the area C.

FIG. 7O illustrates the three areas A, B, and C after the third rinsing wherein the area C retains the layers 703, 704, 705-C, and 706 deposited in FIG. 7B, while the area A retains the layer deposited up to FIG. 7G, and the area B retains the layers deposited up to FIG. 7K.

In FIG. 7P, an optional electron injection layer 712 and subsequently a cathode 713 are deposited to create three QLED subpixels in the three different areas A, B and C.

The thickness of each layers deposited in FIGS. 7A to 7P ranges from 1 to 150 nm.

In some implementations of the present disclosure, a light emitting structure having RGB patterned QLEDs with inverted structures and different types of QDs and HTLs of different thicknesses is provided.

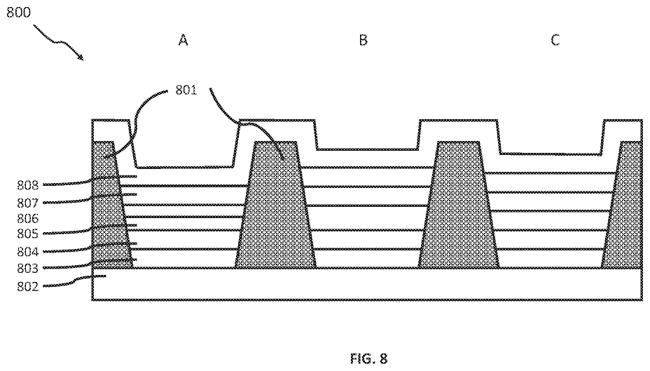

FIG. 8 illustrates a particular implementation obtained from the method described above regarding FIGS. 5A to 5P. In FIG. 8, the example structure 800 includes a bank structure 801, a substrate 802, a cathode layer 803 in each of the areas (e.g., areas A, B, and C), an electron injecting/transporting layer 804 in each of the areas, an emissive layer 805 which may be different in each of the areas, a cross-linkable hole transporting layer 806 in each of the areas, a hole injecting layer 807 in each of the areas, and a anode layer 808 in each of the areas.

When the 505A of QDs A, 505B of QDs B and 505C of QDs C are deposited in FIGS. 5C, 5H and 5L, respectively, each can be deposited at a different thickness. Similarly, X-HTL can be formed in areas A, B and C at different thicknesses, depositing the material of the cross-linkable hole transporting layers at different thicknesses in 5F, 5H and 5L, respectively. The structure of the three different areas A, B, and C, i.e., the subpixels of the display, maybe thus controlled. In the implementations wherein the three QDs of different properties such as conduction and valence energy levels, band gap, etc., are deposited on a same substrate, structures of each subpixel should be different to produce the most efficient devices.

In some implementations of the present disclosure, a light emitting structure having RGB patterned QLEDs with non-inverted structures and different types of QDs and ETL of different thicknesses is provided.

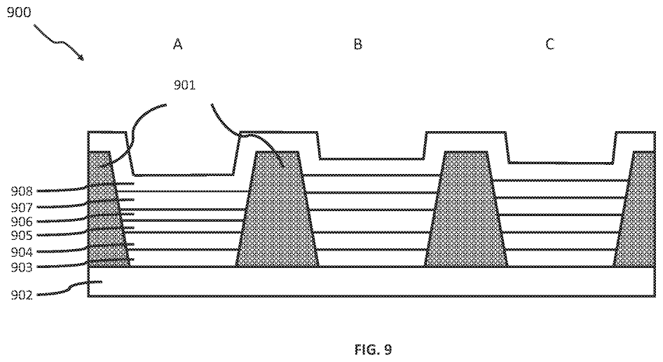

FIG. 9 illustrates a particular implementation obtained from the method described above regarding FIGS. 7A to 7P. In FIG. 9, the example structure 900 includes a bank structure 901, a substrate 902, a anode layer 903 in each of the areas (e.g., areas A, B, and C), a hole injecting/transporting layer 904 in each of the areas, an emissive layer 905 which may be different in each of the areas, a cross-linkable electron transporting layer 906 in each of the areas, an electron injecting layer 907 in each of the areas, and a cathode layer 908 in each of the areas.

When the 705A of QDs A, 705B of QDs B and 705C of QDs C are deposited in FIGS. 7C, 7H and 7L, respectively, each can be deposited at a different thickness. Similarly, X-ETL can be formed in areas A, B and C at different thicknesses, depositing the material cross-linkable electron transporting layers at different thicknesses in FIGS. 7F, 7H and 7L, respectively. The structure of the three different areas A, B, and C, i.e., the subpixels of the display, maybe thus controlled. In the implementations wherein the three QDs of different properties such as conduction and valence energy levels, band gap, etc., are deposited on a same substrate, structures of each subpixel should be different to produce the most efficient devices. The thickness of layers according to FIG. 9 may range from 1 to 150 nm.

In some implementations of the present disclosure, a light emitting structure having RGB patterned QLEDs with inverted structures and different X-HTLs is provided.

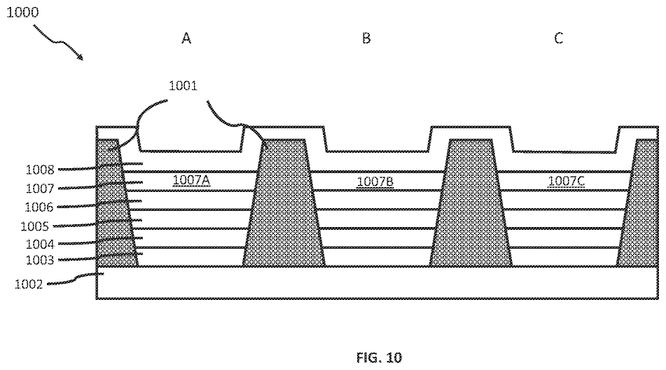

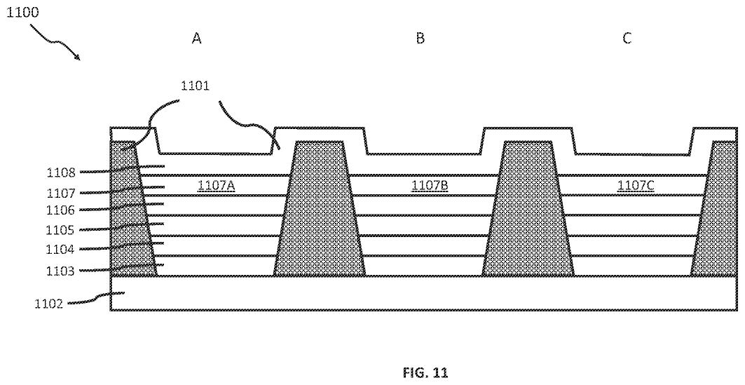

FIG. 10 illustrates a light emitting structure 1000 having patterned QLEDs with inverted structures, each subpixel having a different type of cross-linked hole transporting layer (X-HTL), in accordance with an example implementation of the present disclosure. In FIG. 10, the example structure 1000 includes a bank structure 1001, a substrate 1002, a cathode layer 1003 in each of the areas (e.g., areas A, B, and C), an electron injecting/transporting layer 1004 in each of the areas, an emissive layer 1005 which may be different in each of the areas, a cross-linkable hole transporting layer 1006 in each of the areas, a hole injecting layer 1007 in each of the areas, and a anode layer 1008 in each of the areas.

In one implementation, the example structure 1000 may be obtained from the method described above regarding FIGS. 5A-5P. For example, FIGS. 5F, 5H and 5L may correspond to the deposition of different X-HTMs (three or two different ones). For example, the X-HTL 1007A in area A, the X-HTL 1007B in Area B, and the X-HTL 1007C in area C may be of different cross-linked hole transporting materials and/or different thicknesses.

The example structure 1000 of the three different areas A, B, and C, i.e., the subpixels of the display, may be thus controlled. In the implementations where the three QDs of different properties such as conduction and valence energy levels, band gap, etc., are deposited on a same substrate, structures of each subpixel should be different to produce the most efficient devices.

In some implementations, the light emitting structure of FIG. 10 further includes an electron blocking layer (EBL) between the electron transporting layer and the emissive layer or between the hole transporting layer and the emissive layer. In various implementations of the disclosure, the EBL may be less than 20 nm thick, less than 10 nm thick, or less than 5 nm thick.

In some implementations of the present disclosure, a light emitting structure having RGB patterned QLEDs with non-inverted structures and different X-HTLs is provided.

FIG. 11 illustrates an example light emitting structure 1100 having patterned QLEDs with non-inverted structures, each subpixel having a different type of cross-linked electron transporting layer (X-ETL), in accordance with an example implementation of the present disclosure. In FIG. 11, the example structure 1100 includes a bank structure 1101, a substrate 1002, a anode layer 1103 in each of the areas (e.g., areas A, B, and C), a hole injecting/transporting layer 1104 in each of the areas, an emissive layer 1105 which may be different in each of the areas, a cross-linkable electron transporting layer 1106 in each of the areas, an electron injecting layer 1107 in each of the areas, and a cathode layer 1108 in each of the areas.

In one implementation, the example structure 1100 may be obtained from the method described above regarding FIGS. 7A-7P. For example, FIGS. 7F, 7H and 7L may correspond to the deposition of different X-ETMs (three or two different ones). For example, the X-ETL 1107A in area A, the X-ETL 1107B in Area B, and the X-ETL 1107C in area C may be of different cross-linked electron transporting materials and/or different thicknesses.

The structure of the three different areas A, B, and C, i.e., the subpixels of the display, maybe thus controlled. In the implementations where the three QDs of different properties such as conduction and valence energy levels, band gap, etc., are deposited on the same substrate, structures of each subpixel should be different to produce the most efficient devices.

In some implementations, the light emitting structure of FIG. 11 further includes an electron blocking layer (EBL) between the electron transporting layer and the emissive layer or between the hole transporting layer and the emissive layer or in both positions simultaneously. In various implementations of the disclosure, the EBL may be less than 20 nm thick, less than 10 nm thick, or less than 5 nm thick.

In various implementations of the present disclosure, the solvent used for rinsing is the same solvent used in the deposition of the QDs or of the cross-linkable hole transporting material. In other implementations, the solvent used for rinsing is a similar solvent or orthogonal solvent to the solvent used deposition of the QDs or of the cross-linkable hole transporting material.

Accordingly, as shown in FIGS. 5G, 5K and 5O the QDs layers and the cross-linked portions of the hole transporting layers remains on the deposition surface (the ETL in these cases). The solvent used in the QDs and in the cross-linkable hole transporting material and the solvent used to wash away the remaining mixture may be evaporated during annealing (e.g., heating) of the deposited layer. The annealing may be performed at any suitable temperature that is effective to evaporate the solvent while also maintaining the integrity of the quantum dots, electrodes and charge transport materials. In various implementations of the present disclosure, annealing may be performed at a temperature ranging from 5° C. to 150° C., or at a temperature ranging from 30° C. to 150° C., or at a temperature ranging from 30° C. to 100° C.

In one implementation, subsequent to the application of UV light as shown in FIGS. 5E, 5I and 5M, the layer may be annealed (e.g., heated) to facilitate evaporation and removal of the solvent(s). This annealing may be performed prior to the washing or subsequent to the washing. In implementations in which the annealing is performed prior to the washing, a subsequent annealing may be performed after washing. As another example, application of UV light as shown in FIGS. 5E, 5I and 5M and annealing (e.g., heating) may be performed in parallel. This may remove the solvent used in the deposited solution. Subsequent to the rinsing, a subsequent annealing may be performed. As yet another example, annealing may be conducted prior to application of UV light as shown in FIGS. 5E, 5I and 5M, and subsequent to the rinsing, a subsequent annealing may be performed.

Factors such as the UV exposure times, UV-intensity, amount of photo initiator, type and thickness of the deposition surface (including ligands), surface treatments (as UV-ozone or plasma) and ratio between cross-linkable material and photo initiator may allow for control of the morphology of the emissive material and of the hole transporting layer. For example, UV exposure time may range from 0.001 seconds to 15 minutes, and/or UV exposure intensity may range from 0.001 to 100,000 mJ/cm². The amount of photo initiator may range from 0.001 to 15 wt. % of the total concentration of the cross-linkable material in solution. The concentration of the ligands of the QDs may range from 0 to 35 wt % of the total weight of the QDs. The thickness of the deposition surface may range from 0.1 to 1000 nm. The deposition surface may be composed of any suitable organic, metalorganic or inorganic materials.

In one implementation, the UV exposure intensity ranges from 1 to 100 mJ/cm² at a UV exposure time of 0.01 to 200 seconds, the concentration of the cross-linkable material in the solution may range from 0.5 and 10 wt. %, and the photo initiator concentration ranges from 0 and 5 wt. % of the concentration of the cross-linkable material in solution, and the thickness of the deposition surface ranges from 1 to 1000 nm.

During the fabrication of devices with the above discussed methods, it is important to find the appropriate solvents such that during the deposition of a particular layer, the process will not dissolve or otherwise damage the previously deposited layer. Such a non-damaging solvent is typically referred to in the art as “orthogonal” to the previous one (See Organic Electronics 30 (2016) 18e29; http://dx.doi.org/10.1016/j.orgel.2015.12.008).

In various implementations of the present disclosure, the solvent used for rinsing is the same solvent used in the deposition of the QDs or of the cross-linkable hole transporting material. In other implementations, the solvent used for rinsing is a similar solvent or orthogonal solvent to the solvent used deposition of the QDs or of the cross-linkable hole transporting material.

To deposit multiple layers in a typical QLED structure using solution process methods, solution of different materials in adjacent orthogonal solvents should be deposited. Solution process methods include, but are not limited to, methods of drop casting, spin coating, dip coating, slot die coating, spray coating, and inkjet printing.

In one implementation, the electron transporting material (e.g. ZnO) is dissolved and deposited in Ethanol, the emissive material (e.g. QDs) is dissolved and deposited in octane, the cross-linkable hole transporting material (e.g. OTPD) is dissolved and deposited in toluene (or in PGMEA, or in THF, or in chlorobenzene), the hole injection material (e.g. PEDOT:PSS-MoO3) is dissolved and deposited in an ethanol/2-propanol mixture.

The disclosed substrates may be made from any suitable material(s) as are typically used in light-emitting devices, such as glass substrates and polymer substrates. More specific examples of substrate materials include polyimides, polyethenes, polyethylenes, polyesters, polycarbonates, polyethersulfones, polypropylenes, and/or polyether ether ketones.

The disclosed substrates may be any suitable shape and size. In various implementations of the present disclosure, the dimensions of the substrate allow for more than one light-emitting device to be provided thereon. In an example, a major surface of the substrate may provide an area for multiple light-emitting devices to be formed as sub-pixels of a pixel, with each sub-pixel emitting light of a different wavelength such as red, green, and blue. In another example, a major surface of the substrate may provide an area for multiple pixels to be formed thereon, each pixel including a sub-pixel arrangement of multiple light-emitting devices.

In various implementations of the present disclosure, the disclosed electrodes may be made from any suitable material(s) as are typically used in light-emitting devices. At least one of the electrodes is a transparent or semi-transparent electrode for light emission, and the other of the electrodes is a reflective electrode to reflect any internal light toward the light-emitting side of the device.

In bottom-emitting devices according to various implementations of the present disclosure, the first electrode may be transparent or semi-transparent. Typical materials for the transparent or semi-transparent electrode include indium-doped tin oxide (ITO), fluorine doped tin oxide (FTO) or indium-doped zinc oxide (IZO), aluminum-doped zinc-oxide (AZO), indium-doped cadmium-oxide and other similar materials.

In top-emitting devices according to various implementations of the present disclosure, the first electrode may be made of any suitable reflective metal such as silver or aluminium. In bottom-emitting devices according to various implementations of the present disclosure, the second deposited electrode is a reflective electrode. Suitable materials used for the reflective electrode include metals such as aluminium or silver (cathodes for an existing structure) and gold, aluminium, silver or platinum (anodes for an inverted structure). Top-emitting structures will use a semi-transparent as the second deposited electrode such as thin (<20 nm) silver, a metallic bilayer (e.g. 2 nm Aluminium/15 nm Silver), a silver nanowires layer or a magnesium-silver alloy.

The disclosed electrodes may also be provided in any suitable arrangement. As an example, the electrodes may address a thin-film transistor (TFT) circuit.

In various implementations of the present disclosure, materials for the disclosed QD core and shell include one or more of. InP, CdSe, CdS, CdSeₓS₁₋ₓ, CdTe, CdₓZn₁₋ₓSe, CdₓZn₁₋ₓSe_{y}S_{1-y}, ZnSe, ZnS, ZnSₓTe₁₋ₓ, ZnSeₓTe₁₋ₓ, perovskites of the form ABX₃, Zn_{w}Cu_{z}In_{1-(w+z)}S, and carbon, where 0≤w, x, y, z≤1. Materials for the disclosed ligands include alkyl, -alkenyl, -alkynyl or aryl (linear, branched or cyclic) thiols with 1 to 30 atoms of carbon; alkyl, -alkenyl, -alkynyl or aryl (linear, branched or cyclic) alcohols with 1 to 30 atoms of carbon; alkyl, -alkenyl, -alkynyl or aryl (linear, branched or cyclic) carboxylic acids with 1 to 30 atoms of carbon; tri-alkyl, -alkenyl, -alkynyl or aryl (linear, branched or cyclic) phosphine oxides with 1 to 60 atoms of carbon; alkyl, -alkenyl, -alkynyl or aryl (linear, branched or cyclic) amines with 1 to 30 atoms of carbon; salts formed from any of the above listed compounds (the anion or the cation are the binding moieties); halogen salts (the anion or the cation are the binding moieties).

It will be appreciated that while the present disclosure primarily describes the QDs as core-shell QDs, in some implementations the QDs may not be of the core-shell type or they may be of a core/multiple-shells type having more than one shell. The non-core-shell type QDs may be made from one or more of the above-mentioned materials, and the QDs in accordance with the present disclosure may not include a core-shell configuration.

In various implementations of the present disclosure, a solvent, a mixture of solvents, a mixture or a solution can be used as developer for the QDs and the cross-linkable material not polymerised (and the photo initiator, if included). For example, the solvent may be selected such that the quantum dots, the cross-linkable material when not polymerised (and the photo initiator, if included) is soluble therein.

In various implementations of the present disclosure, example solvents include, but are not limited to, the following or mixtures including the following: acetone, dichloromethane, chloroform, linear or branched alkyl acetates (e.g. ethyl acetate, n-butyl acetate, 2-butyl acetate), linear or branched alkanes with 3 to 30 atoms of carbon (e.g., pentane, hexane, heptane, octane, nonane, decane, undecane, dodecane), linear or branched alcohols with 1 to 20 atoms of carbon (e.g., butanol, 2-propanol, propanol, ethanol, methanol), linear or branched alkoxy alcohols with 2 to 20 atoms of carbon (e.g., 2-Methoxyethanol, 2-Ethoxyethanol), mono, di and tri halogen substituted benzenes (e.g., chlorobenzene, 1,2-dibromobenzene, 1,3-dibromobenzene, 1,4-dibromobenzene, 1,3,5-tribromobenzene, 1,2,4-tribromobenzene), linear or branched ethers with 2 to 20 atoms of carbon, and/or mono, di and tri alkyl substituted benzenes (e.g., toluene, 1,2-Dimethylbenzene, 1,3-Dimethylbenzene, 1,4-Dimethylbenzene), benzene, dioxane, propylene glycol monomethyl ether acetate (PGMEA), 1-methoxy-2-propanol, water.

In various implementations of the present disclosure, example solutions may include any alkaline or acidic material in one or in a mixture of the previously disclosed solvents. The particular solvent or developer that is utilized may depend on the specific QDs, cross-linkable material, and photo initiator that are selected.

In various implementations of the present disclosure, the solvent used for rinsing is the same solvent used in the deposition of the QDs or of the cross-linkable hole transporting material. In other implementations, the solvent used for rinsing is a similar solvent or orthogonal solvent to the solvent used deposition of the QDs or of the cross-linkable hole transporting material.

In various implementations of the present disclosure, example insulating materials for the banks may include, but are not limited to, polyimides. In some examples, the insulating material may include a surface treatment, such as for example fluorine, to modify the insulating material wetting properties.

For example, the insulating material may be made hydrophilic to prevent the deposited material from sticking on the banks and to ensure the subpixel is filled properly. The insulating material thus forms wells and the bottoms may include different electrodes (e.g., anodes) for each subpixel.

In various implementations of the present disclosure, the cross-linked hole transporting layer is formed using one or more photo-initiators. As such, the layer described in this application may include one or more photo-initiators. A photo initiator is a material that initiates polymerization in response to light stimuli. In various implementations of the present disclosure, the photo initiator may generate one or more radicals, ions, acids, and/or species that may initiate such polymerization.

In various implementations of the present disclosure, the initiator is a photo initiator. Example photo initiators include sulfonium- and iodonium-salts (e.g. triphenylsulfonium triflate, diphenyliodonium triflate, iodonium, [4-(octyloxy)phenyl]phenyl hexafluorophosphate, bis(4-methylphenyl)iodonium hexafluorophosphate, diphenyliodonium hexafluoroarsenate, diphenyliodonium hexafluoroantimonate, etc), chromophores containing the benzoyl group (benzoin ether derivatives, halogenated ketones, dialkoxyacetophenones, diphenylacetophenones, etc), hydroxy alkyl heterocyclic or conjugated ketones, benzophenone- and thioxanthone-moiety-based cleavable systems (such as benzophenone phenyl sulfides, ketosulfoxides, etc), benzoyl phosphine oxide derivatives, phosphine oxide derivatives, trichloromethyl triazines, biradical-generating ketones, peroxides, diketones, azides and aromatic bis-azides, azo derivatives, disulfide derivatives, disilane derivatives, diselenide and diphenylditelluride derivatives, digermane and distannane derivatives, peresters, barton's ester derivatives, hydroxamic and thiohydroxamic acids and esters, organoborates, titanocenes, chromium complexes, aluminate complexes, tempo-based alkoxyamines, oxyamines, alkoxyamines, and silyloxyamines.

In various implementations of the present disclosure, when the specific area of the deposited layer is exposed to UV light, the photo initiator initiates the polymerization of the cross-linkable material. QDs, ligands of the QDs, cross-linkable material, charge transporting material, and photo-initiator can be selected to create uniform dispersion in the deposition solvent. Materials with similar polarity indexes can be selected to ensure homogeneity of the deposited mixtures.

In various implementations of the present disclosure, the electron transport and/or electron injection layers may include individual or combinations of. ZnO, 8-quinolinolato lithium (Liq.), LiF, Cs₂CO₃, MgₓZn₁₋ₓO, AlₓZn₁₋ₓO, GaₓZn₁₋ₓO, 2,2′,2″-(1,3,5-benzinetriyl)-tris(1-phenyl-1-H-benzimidazole) (TPBi), TiO2, ZrO2, N4,N4′-Di(naphthalen-1-yl)-N4,N4′-bis(4-vinylphenyl)biphenyl-4,4′-diamine (VNPB), 9,9-Bis[4-[(4-ethenylphenyl)methoxy]phenyl]-N2,N7-di-1-naphthalenyl-N2,N7-diphenyl-9H-Fluorene-2,7-diamine (VB-FNPD), where 0≤x≤1.

In various implementations of the present disclosure, the electron blocking layers may include individual or combinations of: any of the materials used as hole transporting and electron transporting layers, polyethylenimine (PEI) and Polyethylenimine, 80% ethoxylated (PEIE), Poly(methyl methacrylate) (PMMA), molybdenum oxide, aluminium, and the like.

In various implementations of the present disclosure, the hole transport and/or hole injection layers may include individual or combinations of: poly(3,4-ethylenedioxythiophene):poly(styrenesulfonate) (PEDOT:PSS), poly(9,9-dioctylfluorene-co-N-(4-sec-butylphenyl)-diphenylamine) (TFB), poly(9-vinylcarbazole) (PVK), poly(N,N′-bis(4-butylphenyl)-N,N′-bisphenylbenzidine) (PolyTPD), V₂O₅, NiO, CuO, WO₃, MoO₃, 2,3,5,6-tetrafluoro-7,7,8,8-tetracyanoquinodimethane (F4TCNQ), 1,4,5,8,9,11-hexaazatriphenylenehexacarbonitrile (HATCN), N4,N4′-Bis(4-(6-((3-ethyloxetan-3-yl)methoxy)hexyl)phenyl)-N4,N4′-diphenylbiphenyl-4,4′-diamine (OTPD), N4,N4′-Bis(4-(6-((3-ethyloxetan-3-yl)methoxy)hexyloxy)phenyl)-N4,N4′-bis(4-methoxyphenyl)biphenyl-4,4′-diamine (QUPD), N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC), 3,5-di-9H-carbazol-9-yl-N,N-bis[4-[[6-[(3-ethyl-3-oxetanyl)methoxy]hexyl]oxy]phenyl]-benzenamine (Oxe-DCDPA).

In various implementations of the present disclosure, the disclosed cross-linked materials are originated from the polymerisation of a cross-linkable organic (or organo-metallic) material. UV-induced cross-linked charge transport materials include UV-induced cross-linked hole transport materials and/or UV-induced cross-linked electron transport materials. Accordingly, the matrix of one or more UV-induced cross-linked charge transport materials may be formed from one or more types of cross-linkable materials. Such materials include one or more hole transport materials and/or one or more electron transport materials.

In various implementations of the present disclosure, the cross-linkable hole transport material may be a material which is an effective hole transporter both without and with crosslinking. In other implementations, the cross-linkable hole transport material may be a material which is an effective hole transporter only when cross-linked.

In various implementations of the present disclosure, the cross-linkable electron transport material may be a material which is an effective electron transporter both without and with crosslinking. In other implementations, the cross-linkable electron transport material may be a material which is an effective electron transporter only when crosslinked. In some implementations, the cross-linked charge transport materials can include one or more of hole injection materials, electron injection materials, hole blocking materials, electron blocking materials, and/or interconnecting materials (ICM).

In various implementations of the present disclosure, the cross-linkable material from which the UV-induced crosslinked charge transport material may be formed includes at least two moieties with different characteristics. As an example, one of the at least two moieties of the molecule may provide charge transporting properties and another of the at least two moieties of the molecule may provide UV-cross-linking capabilities. Exemplary moieties that may provide charge transporting properties include, but are not limited to, tertiary, secondary, and primary aromatic or aliphatic amines, heterocyclic amines, tryaryl phosphines, and quinolinolates. Exemplary moieties that may provide UV-cross-linking capabilities include, but are not limited to, oxetane, epoxy, thiol, alkane, alkene, alkyne, ketone, azide, and aldehyde units. In some implementations, the two moieties may be connected and there may be a distance of less than 20 nm between them.

In various implementations of the present disclosure, the mixture of the cross-linkable material with the QDs can include a small molecule co-monomer that allows polymerization. The co-monomer may contain at least one functional group X that may interact with a functional group Y of the cross-linkable material. The cross-linkable material may include such functional group Y at two or more molecular sites.

For example, the functional group X may be at two ends of the co-monomer; the functional groups Y may be at two ends of the cross-linkable material. In one implementation, the functional groups X may be a thiol, and the function groups Y may be an alkene or alkyne, or vice versa. In another implementation, the functional groups X may be an azide, and the function groups Y may be an alkane or alkene or alkyne, or vice versa.

Ligands of the QDs, co-monomers and cross-linkable materials included in the mixture can be selected to create uniform dispersion in the deposition solvent. Materials with similar polarity indexes can be selected to ensure homogeneity of the deposited mixtures.

One implementation of a cross-linkable material from which the structure described above may be formed is N4,N4′-Bis(4-(6-((3-ethyloxetan-3-yl)methoxy)hexyl)phenyl)-N4,N4′-diphenylbiphenyl-4,4′-diamine (OTPD), shown below in Formula 1.

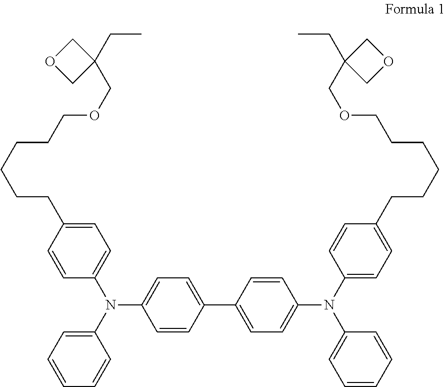 [SMILES: CCC1(COCCCCCCc2ccc(N(c3ccccc3)c3ccc(-c4ccc(N(c5ccccc5)c5ccc(CCCCCCOCC6(CC)COC6)cc5)cc4)cc3)cc2)COC1]

Another example of a cross-linkable material from which the structure described above may be formed is N4,N4′-Bis(4-(6-((3-ethyloxetan-3-yl)methoxy)hexyloxy)phenyl)-N4,N4′-bis(4-methoxyphenyl)biphenyl-4,4′-diamine (QUPD), shown below in Formula 2.

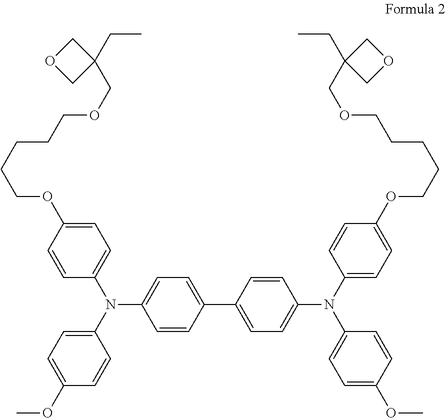 [SMILES: CCC1(COCCCCCOc2ccc(N(c3ccc(OC)cc3)c3ccc(-c4ccc(N(c5ccc(OC)cc5)c5ccc(OCCCCCOCC6(CC)COC6)cc5)cc4)cc3)cc2)COC1]

Another example of a cross-linkable material from which the structure described above may be formed is N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC), shown below in Formula 3.

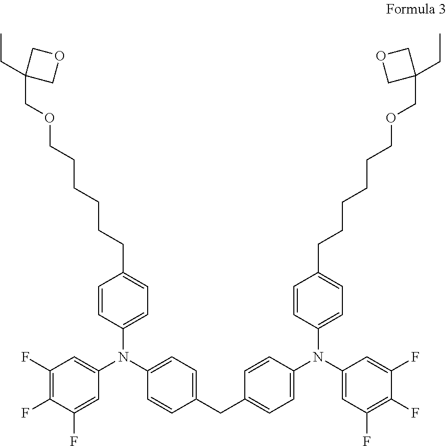 [SMILES: CCC1(COCCCCCCc2ccc(N(c3ccc(Cc4ccc(N(c5ccc(CCCCCCOCC6(CC)COC6)cc5)c5cc(F)c(F)c(F)c5)cc4)cc3)c3cc(F)c(F)c(F)c3)cc2)COC1]

An example of a cross-linkable material from which the structure described above may be formed is N4,N4′-Di(naphthalen-1-yl)-N4,N4′-bis(4-vinylphenyl)biphenyl-4,4′-diamine (VNPB), shown below in Formula 4.

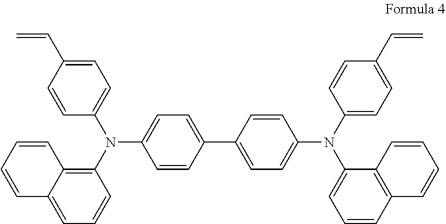 [SMILES: C=Cc1ccc(N(c2ccc(-c3ccc(N(c4ccc(C=C)cc4)c4cccc5ccccc45)cc3)cc2)c2cccc3ccccc23)cc1]

Another example of a cross-linkable material from which the structure described above may be formed is 9,9-Bis[4-[(4-ethenylphenyl)methoxy]phenyl]-N2,N7-di-1-naphthalenyl-N2,N7-diphenyl-9H-Fluorene-2,7-diamine (VB-FNPD), shown below in Formula 5.

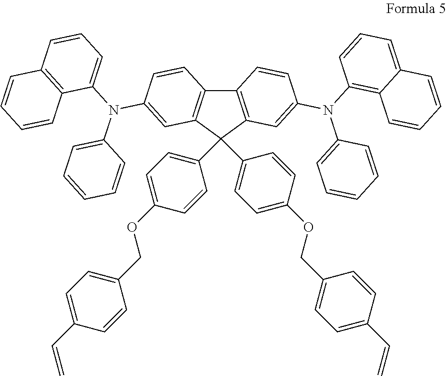 [SMILES: C=Cc1ccc(COc2ccc(C3(c4ccc(OCc5ccc(C=C)cc5)cc4)c4cc(N(c5ccccc5)c5cccc6ccccc56)ccc4-c4ccc(N(c5ccccc5)c5cccc6ccccc56)cc43)cc2)cc1]

Another example of a cross-linkable material from which the structure described above may be formed is 3,5-di-9H-carbazol-9-yl-N,N-bis[4-[[6-[(3-ethyl-3-oxetanyl)methoxy]hexyl]oxy]phenyl]-benzenamine (Oxe-DCDPA), shown below in Formula 6.

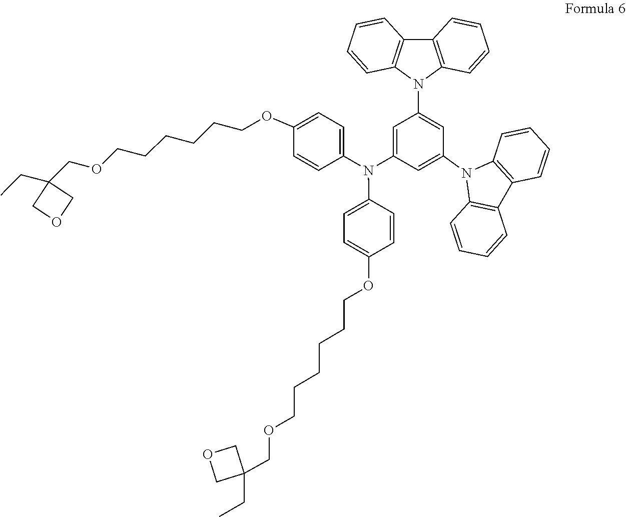 [SMILES: CCC1(COCCCCCCOc2ccc(N(c3ccc(OCCCCCCOCC4(CC)COC4)cc3)c3cc(-n4c5ccccc5c5ccccc54)cc(-n4c5ccccc5c5ccccc54)c3)cc2)COC1]

In various implementations of the present disclosure, for top-emitting devices that include reflective electrodes (e.g. the first electrodes) and partially reflective electrodes (e.g. the second electrode), an optical cavity can be established for the light emitted from QDs by electroluminescence. The distance between the QDs emitting light and the first electrode, and the distance between the QDs emitting light and the second electrode, can have a significant effect on the optical mode of the cavity, and consequently on the properties of the light emitted through the second electrode.

For example, such parameters can affect the efficiency of light escaping from the light emitting device, and the dependence of intensity and wavelength on emission direction. Therefore, it is often preferable to select the thickness of layers disposed between the QDs and the electrodes to provide a favorable optical cavity for optimal light efficiency. Suitable thicknesses are different for different wavelengths of light (e.g. different between a device emitting red light and a device emitting green light).

It is evident that various techniques can be utilized for implementing the concepts described in the present disclosure without departing from the scope of those concepts. Moreover, while the disclosure is with regard to specific implementations, a person of ordinary skill in the art will recognize that changes may be made in form and detail without departing from the scope of the disclosure. As such, the disclosure is to be considered in all respects as illustrative and not restrictive. It should also be understood that the present disclosure is not limited to the particular implementations described since many rearrangements, modifications, and substitutions are possible without departing from the scope of the present disclosure.

What is claimed is:

1. A light-emitting device comprising:
an anode;
a cathode;
an electron transporting or injecting layer between the cathode and the anode;
an emissive layer having quantum dots between the anode and the electron transporting or injecting layer; and
a cross-linked hole transporting or injecting layer between the anode and the emissive layer.

2. The light-emitting device of claim 1, wherein the cross-linked hole transporting or injecting layer comprises a cross-linked material formed by a cross-linkable material cross-linked by at least one of a stimulus or an initiator.

3. The light-emitting device of claim 2, wherein the stimulus is an external stimulus including one of light, a change in temperature, a change in pressure and a change in pH value.

4. The light-emitting device of claim 1, further comprising a hole injecting layer between the cross-linked hole transporting or injecting layer and the anode.

5. The light-emitting device of claim 1, further comprising at least one electron blocking layer, wherein the at least one electron blocking layer is situated in at least one of the following positions:
between the emissive layer and the cross-linked hole transporting layer; and
between the electron transporting layer and the emissive layer.

6. The light-emitting device of claim 2, wherein the initiator is a photo initiator that initiates polymerization of the cross-linkable material in response to a light stimulus.

7. The light-emitting device of claim 6, wherein the light stimulus that activates the photo initiator is in an ultraviolet (UV) wavelength range of an electromagnetic spectrum.

8. The light-emitting device of claim 2, wherein the cross-linkable material is deposited on the emissive layer in a solution.

9. A light-emitting device comprising:
an anode;
a cathode;
a hole transporting or injecting layer between the cathode and the anode;
an emissive layer having quantum dots between the cathode and the hole transporting or injecting layer; and
a cross-linked electron transporting or injecting layer between the cathode and the emissive layer.

10. The light-emitting device of claim 9, wherein the cross-linked electron transporting or injecting layer comprises a cross-linked material formed by a cross-linkable material cross-linked by at least one of a stimulus or an initiator.

11. The light-emitting device of claim 10, wherein the stimulus is an external stimulus including one of light, a change in temperature, a change in pressure and a change in pH value.

12. The light-emitting device of claim 9, further comprising a hole injecting layer between the hole transporting or injecting layer and the anode.

13. The light-emitting device of claim 9, further comprising at least one electron blocking layer, wherein the at least one electron blocking layer is situated in at least one of the following positions:
between the emissive layer and the cross-linked electron transporting layer; and
between the hole transporting layer and the emissive layer.

14. The light-emitting device of claim 10, wherein the initiator is a photo initiator that initiates polymerization of the cross-linkable material in response to a light stimulus.

15. The light-emitting device of claim 14, wherein the light stimulus that activates the photo initiator is in an ultraviolet (UV) wavelength range of an electromagnetic spectrum.

16. The light-emitting device of claim 10, wherein the cross-linkable material is deposited on the emissive layer in a solution.

17. A light emitting structure comprising:
a substrate;
a plurality of sub-pixel structures over the substrate;
wherein at least one of the plurality of sub-pixel structures includes:
an anode;
a cathode;
an electron transporting or injecting layer between the cathode and the anode;
an emissive layer having quantum dots between the anode and the electron transporting or injecting layer; and
a cross-linked hole transporting or injecting layer between the anode and the emissive layer.

18. The light emitting structure of claim 17, wherein the cross-linked hole transporting or injecting layer comprises a cross-linked material formed by a cross-linkable material cross-linked by at least one of a stimulus or an initiator.

19. The light emitting structure of claim 17, wherein a thickness of the emissive layer in each of the plurality of sub-pixel structures is different.

20. The light emitting structure of claim 17, wherein at least one of a thickness and a composition of the cross-linked hole transporting or injecting layer in each of the plurality of sub-pixel structures is different.
